(19) United States
(12) Patent Application Publication
(10) Pub. No.: US 2026/0333752 A1
(43) Pub. Date: Oct. 22, 2026

(54) VERTICAL TRANSISTOR

(71) Applicant: TOYODA GOSEI CO., LTD., Kiyosu-shi (JP)

(72) Inventors: Masayoshi KOSAKI, Kiyosu-shi (JP); Tsutomu INA, Kiyosu-shi (JP); Kazuya HASEGAWA, Kiyosu-shi (JP)

(21) Appl. No.: 19/647,331

(22) Filed: Apr. 14, 2026

(30) Foreign Application Priority Data
Apr. 18, 2025 (JP) 2025-068671

(51) Int. Cl. H10D 30/66; G01R 31/26; H10D 30/01; H10D 62/85

(52) U.S. Cl. CPC H10D 30/668; G01R 31/2621; H10D 30/0297; H10D 62/8503

(57) ABSTRACT

A vertical transistor in which an increase in on-resistance due to switching operation is suppressed. In the vertical transistor having a trench insulated gate structure and using a group III nitride semiconductor, the p-type impurity concentration of the p-type layer (third semiconductor layer 13) is 1×10¹⁹/cm³ or less, and the C concentration of the p-type layer is 3×10¹⁶/cm³ or less. When a switching test is performed for 2 minutes by switching the vertical transistor on and off at a drain current of 350 A/cm², a frequency of 100 kHz, and a duty ratio of 50%, a ratio of the on-resistance after the switching test to the on-resistance before the switching test is 1.1 or less.

### CROSS-REFERENCE

This application claims priority to Japanese patent application No. 2025-068671 filed on Apr. 18, 2025, the contents of which are fully incorporated herein by reference.

### TECHNICAL FIELD

The present disclosure relates to a vertical transistor.

### BACKGROUND ART

Group III nitride semiconductors are known as materials for power devices, and MOSFETs using group III nitride semiconductors have been developed.

Patent Literature 1 discloses a high-quality p-type group III nitride semiconductor with a carbon (C) concentration of less than 5×10¹⁵/cm³.

### PRIOR ART LITERATURE

### Patent Literature

[Patent Literature 1] JP-A-2023-110417

### SUMMARY

The inventors conducted a switching test in which on-off operations were repeatedly performed on a vertical MOSFET using a group III nitride semiconductor. As a result, it was found that the on-resistance increased as the number of switching cycles increased.

The present disclosure was made in view of this background and aims to provide a vertical transistor that an increase in on-resistance due to switching operation is suppressed.

A vertical transistor according to one aspect of the present disclosure relates to a vertical transistor having a trench insulated gate structure and using a group III nitride semiconductor, the vertical transistor includes:
a conductive substrate;
a first n-type layer formed on or above the substrate and made of an n-type group III nitride semiconductor;
a p-type layer formed on or above the first n-type layer and made of a p-type group III nitride semiconductor;
a second n-type layer formed on or above the p-type layer and made of an n-type group III nitride semiconductor having an n-type impurity concentration higher than that of the first n-type layer;
a trench formed in a portion of a surface of the second n-type layer and having a depth reaching the first n-type layer;
a gate insulating film formed on a bottom surface and side surfaces of the trench;
a gate electrode formed on the bottom surface and side surfaces of the trench via the gate insulating film;
a source electrode formed on the second n-type layer; and
a drain electrode formed on a back surface of the substrate, wherein
the p-type layer has a p-type impurity concentration of 1×10¹⁹/cm³ or less and a C concentration of 3×10¹⁶/cm³ or less, and
when a switching test is performed by switching the vertical transistor on and off for 2 minutes at a drain current of 350 A/cm², a frequency of 100 kHz, and a duty ratio of 50%, a ratio of the on-resistance after the switching test to the on-resistance before the switching test is 1.1 or less.

A vertical transistor according to another aspect of the present disclosure relates to a vertical transistor having a trench insulated gate structure and using a group III nitride semiconductor, the vertical transistor includes:
a conductive substrate;
a first n-type layer formed on or above the substrate and made of an n-type group III nitride semiconductor;
a p-type layer formed on or above the first n-type layer and made of a p-type group III nitride semiconductor;
a second n-type layer formed on or above the p-type layer and made of an n-type group III nitride semiconductor having an n-type impurity concentration higher than that of the first n-type layer;
a trench formed in a portion of a surface of the second n-type layer and having a depth reaching the first n-type layer;
a gate insulating film formed on a bottom surface and side surfaces of the trench;
a gate electrode formed on the bottom surface and side surfaces of the trench via the gate insulating film;
a source electrode formed on the second n-type layer; and
a drain electrode formed on a back surface of the substrate, wherein
a p-type impurity concentration and a C concentration of the p-type layer, a thickness of the substrate, and a thickness of the drain electrode are set so that a ratio of the on-resistance after the switching test to the on-resistance before the switching test is 1.1 or less when a switching test is performed by switching the vertical transistor on and off for 2 minutes at a drain current of 350 A/cm², a frequency of 100 kHz, and a duty ratio of 50%.

A vertical transistor according to still another aspect of the present disclosure includes:
a conductive substrate;
a first n-type layer formed on or above the substrate and made of an n-type group III nitride semiconductor;
a p-type layer formed on or above the first n-type layer and made of a p-type group III nitride semiconductor;
a second n-type layer formed on or above the p-type layer and made of an n-type group III nitride semiconductor having an n-type impurity concentration higher than that of the first n-type layer;
a third n-type layer formed between the first n-type layer and the p-type layer and made of an n-type group III nitride semiconductor having an n-type impurity concentration lower than that of the first n-type layer;
a trench formed in a portion of a surface of the second n-type layer and having a depth reaching the third n-type layer;
a gate insulating film formed on a bottom surface and side surfaces of the trench;
a gate electrode formed on the bottom surface and side surfaces of the trench via the gate insulating film;
a source electrode formed on the second n-type layer; and
a drain electrode formed on a back surface of the substrate.

In the above aspect, the p-type layer has a p-type impurity concentration of 1×10¹⁹/cm³ or less and a C concentration of 3×10¹⁶/cm³ or less, and when a switching test is performed by switching the vertical transistor on and off for 2 minutes at a drain current of 350 A/cm², a frequency of 100 kHz, and a duty ratio of 50%, a ratio of the on-resistance after the switching test to the on-resistance before the switching test is 1.1 or less.

Moreover, the third n-type layer having an n-type impurity concentration lower than that of the first n-type layer is formed between the first n-type layer and the p-type layer. This can suppress the increase in on-resistance due to switching operation.

According to the above aspects, a vertical transistor can be provided in which the increase in on-resistance due to switching operation is suppressed.

### BRIEF DESCRIPTION OF THE DRAWINGS

FIG. 1 is a cross-sectional view showing a structure of a semiconductor device according to a first embodiment, taken perpendicular to a main surface of a substrate;

FIG. 2 is a flowchart showing a manufacturing process of the semiconductor device according to the first embodiment;

FIG. 3 is a cross-sectional view showing a structure at each step of the manufacturing process of the semiconductor device according to the first embodiment, taken perpendicular to the main surface of the substrate;

FIG. 4 is a cross-sectional view showing a structure at each step of the manufacturing process of the semiconductor device according to the first embodiment, taken perpendicular to the main surface of the substrate;

FIG. 5 is a cross-sectional view showing a structure at each step of the manufacturing process of the semiconductor device according to the first embodiment, taken perpendicular to the main surface of the substrate;

FIG. 6 is a circuit diagram of a resistive load circuit;

FIG. 7 is a diagram showing switching waveforms;

FIG. 8 is a graph showing the relationship between gate-source voltage and drain current;

FIG. 9 is a graph showing the relationship between switching time and on-resistance;

FIG. 10 is a graph showing the relationship between number of cycles and on-resistance;

FIG. 11 is a graph showing the relationship between number of cycles and on-resistance;

FIG. 12 is a graph showing the relationship between drain current density during switching test and change ratio of on-resistance;

FIG. 13 is a graph showing the relationship between V/III ratio and C concentration;

FIG. 14 is a graph showing the relationship between drain current density and change ratio of on-resistance during switching test;

FIG. 15 is a graph showing the relationship between drain current density during switching test and change ratio of on-resistance;

FIG. 16 is a graph showing the relationship between drain current density during switching test and change ratio of on-resistance; and

FIG. 17 is a cross-sectional view showing a structure of a semiconductor device according to a modified embodiment of the first embodiment, taken perpendicular to a main surface of a substrate.

### DETAILED DESCRIPTION

The first vertical transistor is a vertical transistor having a trench insulated gate structure and using a group III nitride semiconductor, the vertical transistor includes a conductive substrate; a first n-type layer formed on or above the substrate and made of an n-type group III nitride semiconductor; a p-type layer formed on or above the first n-type layer and made of a p-type group III nitride semiconductor; a second n-type layer formed on or above the p-type layer and made of an n-type group III nitride semiconductor having an n-type impurity concentration higher than that of the first n-type layer; a trench formed in a portion of a surface of the second n-type layer and having a depth reaching the first n-type layer; a gate insulating film formed on a bottom surface and side surfaces of the trench, a gate electrode formed on the bottom surface and side surfaces of the trench via the gate insulating film, a source electrode formed on the second n-type layer, and a drain electrode formed on a back surface of the substrate, wherein the p-type layer has a p-type impurity concentration of 1×10¹⁹/cm³ or less and a C concentration of 3×10¹⁶/cm³ or less, and when a switching test is performed by switching the vertical transistor on and off for 2 minutes at a drain current of 350 A/cm², a frequency of 100 kHz, and a duty ratio of 50%, a ratio of the on-resistance after the switching test to the on-resistance before the switching test is 1.1 or less.

In the first vertical transistor, a third n-type layer made of an n-type group III nitride semiconductor having an n-type impurity concentration lower than that of the first n-type layer may be provided between the first n-type layer and the p-type layer. The trench may have a depth reaching the third n-type layer, and the n-type impurity concentration of the first n-type layer may be 5×10¹⁵/cm³ or more.

Furthermore, the second vertical transistor includes a conductive substrate; a first n-type layer formed on or above the substrate and made of an n-type group III nitride semiconductor; a p-type layer formed on or above the first n-type layer and made of a p-type group III nitride semiconductor; a second n-type layer formed on or above the p-type layer and made of an n-type group III nitride semiconductor having an n-type impurity concentration higher than that of the first n-type layer; a third n-type layer formed between the first n-type layer and the p-type layer and made of an n-type group III nitride semiconductor having an n-type impurity concentration lower than that of the first n-type layer; a trench formed in a portion of a surface of the second n-type layer and having a depth reaching the third n-type layer; a gate insulating film formed on a bottom surface and side surfaces of the trench; a gate electrode formed on the bottom surface and side surfaces of the trench via the gate insulating film; a source electrode formed on the second n-type layer; and a drain electrode formed on a back surface of the substrate.

In the above vertical transistor, the substrate may have a thickness of 300 μm or more. This can further suppress the increase in on-resistance due to switching operation.

In the above vertical transistor, the p-type layer may have a C concentration of 3×10¹⁵/cm³ or less. This can further suppress the increase in on-resistance due to switching operation.

In the above vertical transistor, the drain electrode may have a thickness of 1000 nm or less. This can further suppress the increase in on-resistance due to switching operation.

In the above vertical transistor, the third n-type layer may have an n-type impurity concentration less than or equal to ¾ of the n-type impurity concentration of the first n-type layer. This can further suppress the increase in on-resistance due to switching operation.

In the above vertical transistor, a fourth n-type layer made of an n-type group III nitride semiconductor may be provided between the first n-type layer and the third n-type layer. The fourth n-type layer may have an n-type impurity concentration higher than that of the first n-type layer and lower than that of the second n-type layer. This can reduce the on-resistance.

In the above vertical transistor, the distance from a lower surface of the third n-type layer to the bottom surface of the trench may be 0.1 to 2.0 μm. This can further suppress the increase in on-resistance due to switching operation.

In the above vertical transistor, the distance from the lower surface of the third n-type layer to the bottom surface of the trench may be 0.1 to 0.9 times the thickness of the third n-type layer. This can further suppress the increase in on-resistance due to switching operation.

In the above vertical transistor, when a switching test is performed by switching the vertical transistor on and off for 2 minutes at a drain current of 350 A/cm², a frequency of 100 kHz, and a duty ratio of 50%, a ratio of the on-resistance after the switching test to the on-resistance before the switching test may be 1.1 or less.

### First Embodiment

### 1. STRUCTURE OF SEMICONDUCTOR DEVICE

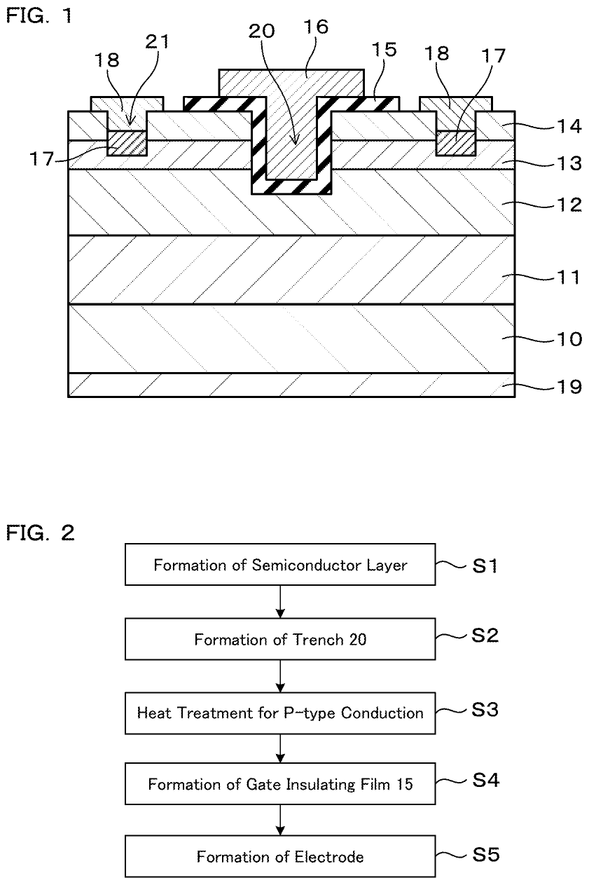

FIG. 1 is a cross-sectional view showing a structure of a semiconductor device according to a first embodiment, taken perpendicular to a main surface of a substrate. The semiconductor device according to the first embodiment is a MOSFET having a vertical trench gate structure. As shown in FIG. 1, the semiconductor device according to the first embodiment includes a substrate 10, a first semiconductor layer 11 (first n-type layer), a second semiconductor layer 12 (third n-type layer), a third semiconductor layer 13 (p-type layer), a fourth semiconductor layer 14 (second n-type layer), a gate insulating film 15, a gate electrode 16, a body electrode 17, a source electrode 18, and a drain electrode 19.

The substrate 10 is a substrate made of Si-doped n⁺-GaN having a c-plane as a main surface. The Si concentration of the substrate 10 is 1×10¹⁸/cm³ or more. The thickness of the substrate 10 is preferably 300 μm or more. The internal stress generated by forming the drain electrode 19 on a back surface of the substrate 10 can be relaxed by increasing the thickness of the substrate 10, thereby suppressing carrier trapping in the vicinity of the trench 20. As a result, the increase in on-resistance due to switching operation can be suppressed. The thickness of the substrate 10 is more preferably 325 to 800 μm, and even more preferably 350 to 700 μm.

In the first embodiment, GaN is used as the material for the substrate 10, but it is not limited to GaN. As long as the material is any conductive material that can be lattice-matched with a group III nitride semiconductor, for example, group III nitride semiconductor other than GaN, Si, SiC and others may be used. Furthermore, although Si is used as the n-type impurity in the first embodiment, other elements known as n-type impurities for group III nitride semiconductors may also be used.

The first semiconductor layer 11 is formed on or above the substrate 10 and is a semiconductor layer made of Si-doped n⁻-GaN. The first semiconductor layer 11 functions as a drift layer. The thickness of the first semiconductor layer 11 is 2 to 15 μm. Furthermore, the Si concentration of the first semiconductor layer 11 is lower than the Si concentration of the substrate 10, for example, 1×10¹⁵ to 3×10¹⁶/cm³. A base layer made of highly Si-doped n⁺-GaN may be provided between the substrate 10 and the first semiconductor layer 11.

The second semiconductor layer 12 is formed on or above the first semiconductor layer 11 and is a semiconductor layer made of Si-doped n⁻-GaN. The Si concentration of the second semiconductor layer 12 is lower than the Si concentration of the first semiconductor layer 11, for example, 1×10¹⁴ to 1×10¹⁶/cm³. By forming the second semiconductor layer 12, the carrier concentration in the region in the vicinity of the trench 20 is reduced, thereby decreasing the electric field strength applied to the gate during the off operation. This can suppress carrier trapping in the vicinity of the trench 20. Consequently, the increase in on-resistance due to switching operation can be suppressed.

The Si concentration of the second semiconductor layer 12 is preferably less than or equal to ¾ of the Si concentration of the first semiconductor layer 11. This can further suppress the increase in on-resistance due to switching operation. The Si concentration of the second semiconductor layer 12 is more preferably, less than or equal to ½ of the Si concentration of the first semiconductor layer 11, and even more preferably, less than or equal to ¼.

Furthermore, the thickness of the second semiconductor layer 12 is set to any value according to the desired device characteristics. The thickness of the second semiconductor layer 12 is, for example, 0.2 to 2 μm.

The distance from the lower surface of the second semiconductor layer 12 to the bottom surface of the trench 20 is preferably 0.1 to 0.9 times the thickness of the second semiconductor layer 12. This can further suppress the increase in on-resistance due to switching operation. For similar reasons, the distance from the lower surface of the second semiconductor layer 12 to the bottom surface of the trench 20 is preferably 0.1 to 2.0 μm. Also, for similar reasons, the distance from the bottom surface of the trench 20 to the top surface of the second semiconductor layer 12 is preferably 0.1 to 2.0 μm.

The third semiconductor layer 13 is formed on or above the second semiconductor layer 12 and is a semiconductor layer made of Mg-doped p-GaN. The third semiconductor layer 13 functions as a channel layer. The thickness of the third semiconductor layer 13 is 0.1 to 1 μm. Furthermore, the Mg concentration of the third semiconductor layer 13 is, for example, 1×10¹⁷ to 8×10¹⁹/cm³. Although Mg is used as the p-type impurity in the first embodiment, other elements known as p-type impurities for group III nitride semiconductors may also be used. The Mg concentration of the third semiconductor layer 13 is more preferably 1×10¹⁹/cm³ or less, and even more preferably 6×10¹⁸/cm³ or less. This can further reduce the change ratio of on-resistance.

The C concentration of the third semiconductor layer 13 is preferably 3×10¹⁶/cm³ or less. This can suppress the increase in on-resistance due to switching operation. The C concentration of the third semiconductor layer 13 is more preferably 3×10¹⁵/cm³ or less, and even more preferably 2×10¹⁵/cm³ or less. Furthermore, by setting the Mg concentration of the third semiconductor layer 13 to 1×10¹⁹/cm³ or less and the C concentration to 3×10¹⁶/cm³ or less, the change ratio of on-resistance can be readily suppressed to 1.1 or less.

The fourth semiconductor layer 14 is formed on or above the third semiconductor layer 13 and is a semiconductor layer made of Si-doped n⁺-GaN. The fourth semiconductor layer 14 functions as a source contact layer. The thickness of the fourth semiconductor layer 14 is 0.1 to 0.5 μm. Furthermore, the Si concentration of the fourth semiconductor layer 14 is higher than the Si concentration of the first semiconductor layer 11 or the second semiconductor layer 12, for example, 1×10¹⁸ to 1×10¹⁹/cm³.

The trench 20 is formed in a portion of the surface of the fourth semiconductor layer 14. The trench 20 is a recess extending through the fourth semiconductor layer 14 and the third semiconductor layer 13 to reach the second semiconductor layer 12. The second semiconductor layer 12 is exposed on the bottom of the trench 20. Thus, by forming the trench 20 to a depth that reaches the second semiconductor layer 12, the increase in on-resistance due to switching operation can be suppressed. Furthermore, on the sides of the trench 20, the second semiconductor layer 12, the third semiconductor layer 13, and the fourth semiconductor layer 14 are exposed in this order from the bottom. The third semiconductor layer 13 exposed on the sides of the trench 20 functions as a channel.

A recess 21 is formed in a portion of the fourth semiconductor layer 14, which is different from the region where the trench 20 is formed. The recess 21 is a depression extending through the fourth semiconductor layer 14 to reach the third semiconductor layer 13.

The gate insulating film 15 is continuously formed over the bottom surface, side surfaces, and top surface of the trench 20. Here, the top surface of the trench 20 refers to a region in the vicinity of the trench 20 of the surface of the fourth semiconductor layer 14. The gate insulating film 15 is made of SiO₂. In addition to SiO₂, SiN, AlN, Al₂O₃, ZrO₂, HfO₂, SiON, AlON, ZrON, HfON, and other materials may also be used for the gate insulating film 15. Furthermore, the gate insulating film 15 may be a multilayer made of these materials.

The gate electrode 16 is an electrode formed over the bottom surface, side surfaces, and top surface of the trench 20 via the gate insulating film 15. The gate electrode 16 is made of, for example, Al. Materials other than Al, such as TiN, Ti, or polysilicon, can also be used for the gate electrode 16.

The body electrode 17 is an electrode formed on the bottom surface of the recess 21. Since the third semiconductor layer 13 is exposed on the bottom of the recess 21, the body electrode 17 contacts the third semiconductor layer 13. The body electrode 17 is made of, for example, Pd. Alternatively, materials such as Ni or a multilayer film formed by depositing Ti and Al in this order from the third semiconductor layer 13 side, can be used. The body electrode 17 and the source electrode 18 may be formed integrally by using the same material as the source electrode 18.

The source electrode 18 is an electrode formed on the fourth semiconductor layer 14 and on the body electrode 17. The source electrode 18 is, for example, a multilayer film formed by depositing Ti and Al in this order from the fourth semiconductor layer 14 side. Alternatively, it may be a multilayer film formed by depositing Ti, Al, Ni, and Au in this order from the fourth semiconductor layer 14 side. The source electrode 18 may be formed separately from the body electrode 17.

The drain electrode 19 is an electrode formed on the back surface of the substrate 10. The drain electrode 19 is a multilayer film formed by depositing Ti, an Al-containing layer, Ti, TiN, Ti, Ni, and an Ag-containing layer in this order from the substrate 10 side. The Ag-containing layer serves as a layer for achieving favorable solder bonding. The Ag-containing layer is made of Ag or an alloy with Ag as its primary component.

The thickness of the drain electrode 19 is preferably 1000 nm or less. This can suppress the increase in on-resistance due to switching operation. The internal stress generated by forming the drain electrode 19 on the back surface of the substrate 10 can be reduced by making the drain electrode 19 thinner. This can suppress carrier trapping in the vicinity of the trench 20. Consequently, the increase in on-resistance due to switching operation can be suppressed.

The thickness of the drain electrode 19 is preferably 800 nm or less, more preferably 500 nm or less. The lower limit of the thickness of the drain electrode 19 may be any value as long as its function as an electrode is maintained, for example, 200 nm or more.

The thickness of the drain electrode 19 is preferably adjusted by using the Ag-containing layer. Although it may be adjusted using layers other than the Ag-containing layer, those layers are generally thin except for the outermost solder bonding layer. Therefore, as in the first embodiment, it is preferable to adjust the thickness of the drain electrode 19 by varying the thickness of the solder bonding layer.

In the semiconductor device according to the first embodiment, when a switching test is performed by switching the device on and off for 2 minutes at a drain current of 350 A/cm², a frequency of 100 kHz, and a duty ratio of 50%, the ratio of the on-resistance after the switching test to the on-resistance before the switching test is 1.1 or less. In other words, the increase in on-resistance due to switching operation is small.

As described above, according to the semiconductor device of the first embodiment, the increase in on-resistance due to switching operation can be suppressed.

### 2. METHOD FOR MANUFACTURING SEMICONDUCTOR DEVICE

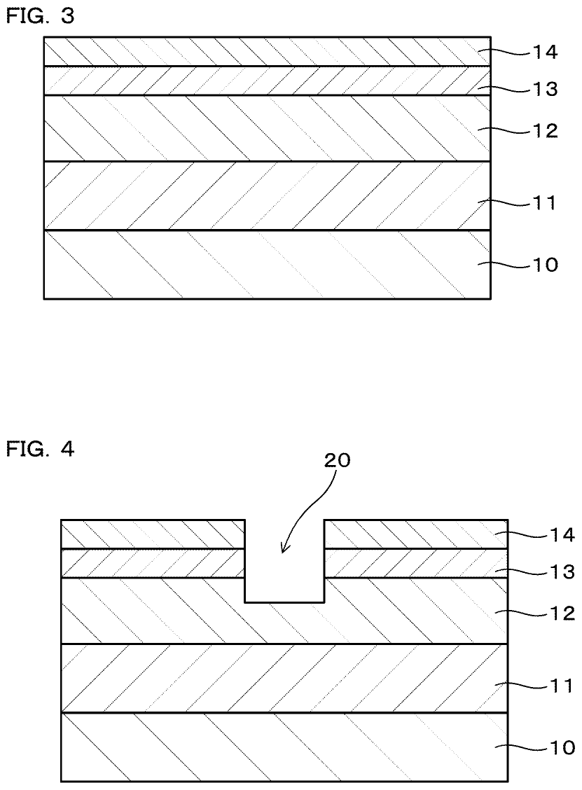

The manufacturing process of the semiconductor device according to the first embodiment will next be described with reference to FIGS. 2 to 5. FIG. 2 is a flowchart showing the manufacturing process. FIGS. 3 to 5 are cross-sectional views showing the structures at each step of the manufacturing process, taken perpendicular to the main surface of the substrate.

Firstly, on a substrate 10, a first semiconductor layer 11, a second semiconductor layer 12, a third semiconductor layer 13, and a fourth semiconductor layer 14 are formed in this order from the substrate 10 side by MOCVD (step S1 in FIG. 2, refer to FIG. 3).

The V/III ratio during the formation of the third semiconductor layer 13 is preferably 1500 or more. The C concentration of the third semiconductor layer 13 can be controlled by the V/III ratio, and by setting the V/III ratio to 1500 or more, the C concentration can be set to 1×10¹⁶/cm³ or less. This can suppress the increase in on-resistance due to switching operation. The V/III ratio during the formation of the third semiconductor layer 13 is more preferably 2500 or more, and even more preferably 3500 or more. No particular upper limit is specified for the V/III ratio, as long as crystal growth of the group III nitride semiconductor can be achieved.

Next, a predetermined region of the surface of the fourth semiconductor layer 14 is dry etched. Dry etching is performed until the second semiconductor layer 12 is exposed. Thus, a trench 20 is formed having a depth reaching from the surface of the fourth semiconductor layer 14 to the second semiconductor layer 12 (step S2 in FIG. 2, refer to FIG. 4). A recess 21 may be formed before or after the formation of the trench 20.

Subsequently, a heat treatment is performed to activate the p-type conductivity of the third semiconductor layer 13 (step S3 in FIG. 2). The heat treatment is performed, for example, at 800 °C in a nitrogen atmosphere.

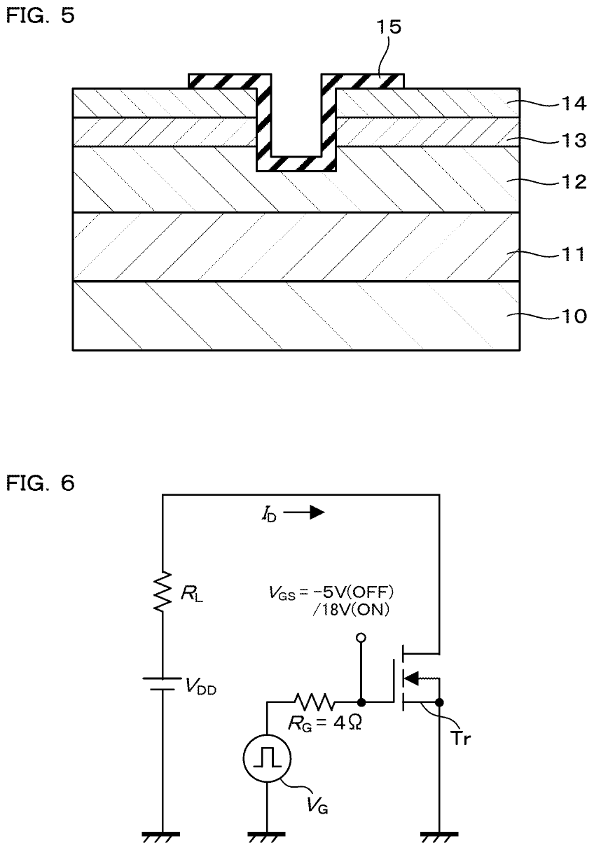

Then, a gate insulating film 15 is continuously formed over the bottom surface, side surfaces, and top surface of the trench 20 (step S4 in FIG. 2, refer to FIG. 5). The top surface of the trench 20 refers to a region in the vicinity of the trench 20 of the surface of the fourth semiconductor layer 14. The gate insulating film 15 is formed by methods such as ALD or CVD.

After that, the recess 21 is formed, and a gate electrode 16, a body electrode 17, a source electrode 18, and a drain electrode 19 are formed (step S5 in FIG. 2). The electrodes are formed, for example, by deposition and patterned by lift-off. Through the above steps, the semiconductor device according to the first embodiment shown in FIG. 1 is manufactured.

### 3. EXPERIMENTAL RESULTS

Next, various experimental results concerning the semiconductor device of the first embodiment are described.

### Experiment 1

A semiconductor device (MOSFET) was manufactured in which the second semiconductor layer 12 was omitted from the semiconductor device according to the first embodiment. The thickness of the substrate 10 was 350 μm, the Si concentration of the first semiconductor layer 11 was 6×10¹⁵/cm³, the Mg concentration of the third semiconductor layer 13 was 1.5×10¹⁹/cm³, the C concentration of the third semiconductor layer 13 was 1×10¹⁶/cm³, and the thickness of the drain electrode 19 was 2000 nm. The thickness of the drain electrode 19 was adjusted by the thickness of the Ag-containing layer. The substrate 10 was a c-plane GaN substrate with an offset angle of 0.5 degrees in the m-axis direction with respect to the c-axis. Furthermore, the V/III ratio for forming each semiconductor layer other than the third semiconductor layer 13 was 3500, and the growth temperature was 1080 °C. The V/III ratio for forming the third semiconductor layer 13 was 1500, and the growth temperature was 1080 °C. The thickness of the base layer was 0.2 μm, the thickness of the first semiconductor layer 11 was 9 μm, the thickness of the third semiconductor layer 13 was 0.3 μm, and the thickness of the fourth semiconductor layer 14 was 0.2 μm.

For the MOSFET manufactured as described above (hereinafter referred to as the vertical MOSFET of Experimental Example 1), a switching test was performed using the resistive load circuit shown in FIG. 6. In FIG. 6, Tr is the MOSFET of Experimental Example 1. As shown in FIG. 6, the source of the MOSFET of Experimental Example 1 was grounded, the gate was connected to a voltage source VG via a gate resistor RG, and the drain was connected to a DC power source VDD via a resistor RL. The voltage source VG is a power source that generates a rectangular wave.

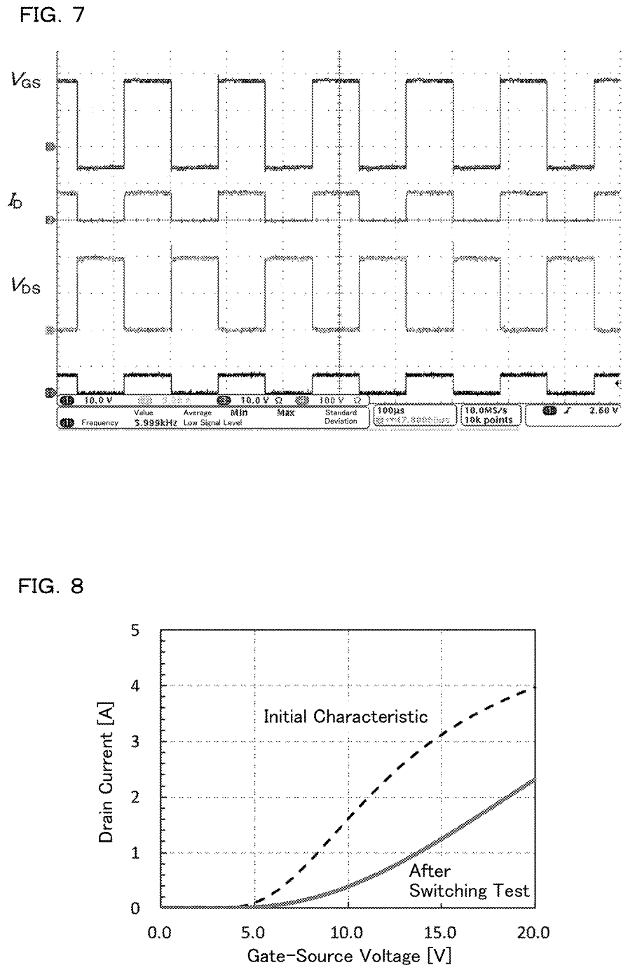

The conditions of the switching test were as follows. The gate voltage was −5 V in the off state and 18 V in the on state; the gate resistance RG was 4Ω; the drain voltage in the off state was 200 V; the drain current was 2 A; the frequency was 6 kHz; the duty ratio was 50%; and the test duration was 30 minutes. FIG. 7 is a graph showing the switching waveforms of the gate voltage, drain current, and drain voltage.

Before and after the switching test, the transfer characteristics of the gate voltage and the drain current (the relationship between the gate voltage and the drain current) were measured. FIG. 8 is a graph showing the transfer characteristics of the MOSFET of Experimental Example 1. As shown in FIG. 8, it was found that after the switching test, the drain current decreased, indicating that the on-resistance increased. A similar phenomenon was observed even when a switching test was performed using an inductive load instead of a resistive load.

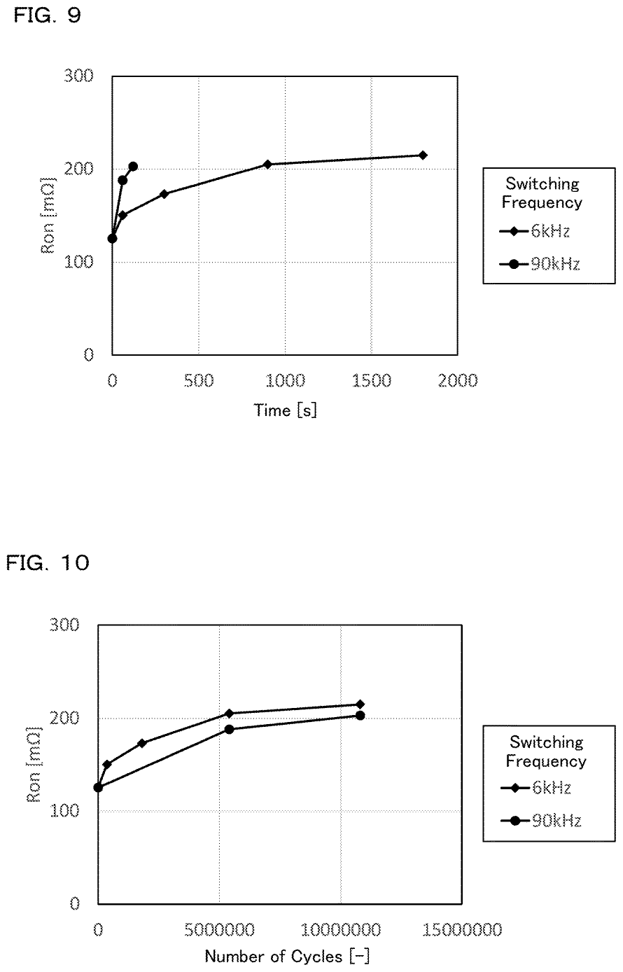

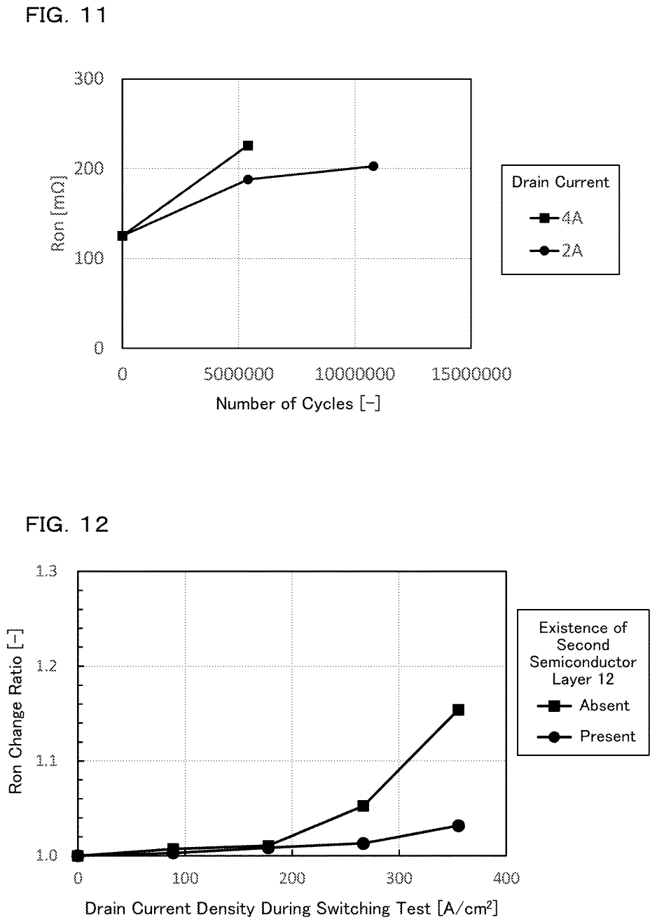

Next, the switching test was performed at two switching frequencies, 6 kHz and 90 kHz, and the on-resistance after the switching test was measured. FIG. 9 is a graph showing the relationship between the switching time of the switching test and the on-resistance. FIG. 10 is a graph showing the relationship between the number of switching cycles (number of cycles) in the switching test and the on-resistance.

From FIGS. 9 and 10, it was found that the change in the on-resistance is caused not by the switching time but by the increase in the number of cycles. It was also found that the increase in on-resistance becomes saturated as the switching is repeated.

Next, the switching test was performed at two drain currents, 2 A and 4 A, and the on-resistance after the switching test was measured. FIG. 11 is a graph showing the relationship between the number of cycles in the switching test and the on-resistance.

As shown in FIG. 11, it was found that the larger the drain current during switching is, the larger the change in the on-resistance becomes.

The increase in on-resistance due to switching operation is considered to be caused by carrier trapping in the vicinity of the trench 20. As the semiconductor device is repeatedly switched on and off, carriers are gradually trapped, resulting in an increase in on-resistance. Furthermore, since carrier trapping is more likely to occur with larger drain current, the on-resistance was further increased.

### Experiment 2

A semiconductor device (MOSFET) was manufactured in which the second semiconductor layer 12 was omitted from the semiconductor device according to the first embodiment (hereinafter referred to as the vertical MOSFET of Experimental Example 2-1). The thickness of the substrate 10 is 350 μm, the Si concentration of the first semiconductor layer 11 is 8×10¹⁵/cm³, the Mg concentration of the third semiconductor layer 13 was 6×10¹⁸/cm³, the C concentration of the third semiconductor layer 13 was 1×10¹⁶/cm³, and the thickness of the drain electrode 19 was 2000 nm.

Furthermore, a vertical MOSFET was manufactured in which a second semiconductor layer 12 was added to the vertical MOSFET of Experimental Example 2-1 (hereinafter referred to as the vertical MOSFET of Experimental Example 2-2). The thickness of the second semiconductor layer 12 was 0.5 μm. Switching tests were then performed on the vertical MOSFETs of Experimental Examples 2-1 and 2-2.

The conditions of the switching test were as follows. The gate voltage was −5 V in the off state and 18 V in the on state; the gate resistance RG was 4Ω; the drain voltage in the off state was 200 V; the frequency was 100 kHz; the duty ratio was 50%; and the test duration was 2 minutes (1.2×10⁷ cycles). The drain current was varied from 0 to 8 A.

The change ratio of on-resistance after the switching test (the ratio of the on-resistance after the switching test to the on-resistance before the switching test) was measured. FIG. 12 is a graph showing the relationship between the drain current density during the switching test and the change ratio of on-resistance after the switching test.

As shown in FIG. 12, it was found that adding the second semiconductor layer 12 can reduce the change ratio of on-resistance after the switching test. In particular, for the vertical MOSFET of Experimental Example 2-2, the change ratio of on-resistance was 1.03, which was able to be controlled at 1.1 or less.

### Experiment 3

A vertical MOSFET was manufactured in which the second semiconductor layer 12 was omitted from the semiconductor device according to the first embodiment. The thickness of the substrate 10 was 350 μm, the Si concentration of the first semiconductor layer 11 was 8×10¹⁵/cm³, the Mg concentration of the third semiconductor layer 13 was 6×10¹⁸/cm³, the C concentration of the third semiconductor layer 13 was 5×10¹⁶/cm³, and the thickness of the drain electrode 19 was 2000 nm. Hereafter, this vertical MOSFET is referred to as the vertical MOSFET of Experimental Example 3-1.

Furthermore, a vertical MOSFET having the same structure as that of Experimental Example 3-1 was manufactured, except that the C concentration of the third semiconductor layer 13 was changed to 1×10¹⁶/cm³. Hereinafter, this vertical MOSFET is referred to as the vertical MOSFET of Experimental Example 3-2.

Additionally, a vertical MOSFET having the same structure as that of Experimental Example 3-1 was manufactured, except that the C concentration of the third semiconductor layer 13 was changed to 2×10¹⁵/cm³. Hereafter, this vertical MOSFET is referred to as the vertical MOSFET of Experimental Example 3-3. Switching tests were then performed on the vertical MOSFETs of Experimental Examples 3-1, 3-2, and 3-3, in the same manner as in Experiment 2.

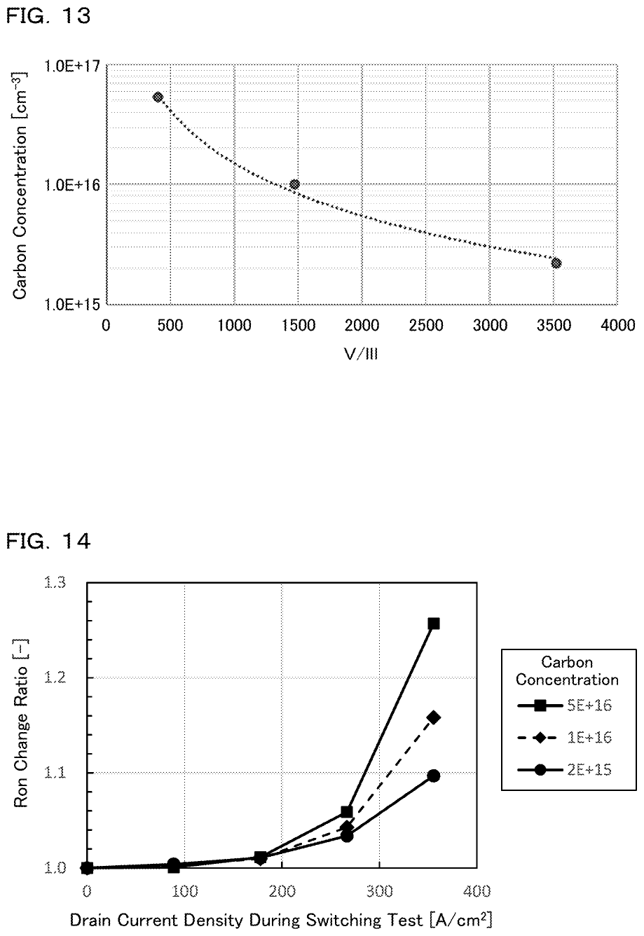

The C concentration of the third semiconductor layer 13 was controlled by the V/III ratio during the formation of the third semiconductor layer 13. FIG. 13 is a graph showing the relationship between the V/III ratio and the C concentration.

FIG. 14 is a graph showing the relationship between the drain current density during the switching test and the change ratio of on-resistance after the switching test. As shown in FIG. 14, it was found that reducing the C concentration of the third semiconductor layer 13 can reduce the change ratio of on-resistance after the switching test. In particular, for the vertical MOSFET of Experimental Example 3 -3 in which the C concentration of the third semiconductor layer 13 was 2×10¹⁵/cm³, the change ratio of on-resistance was able to be controlled at 1.1.

### Experiment 4

A vertical MOSFET was manufactured in which the second semiconductor layer 12 was omitted from the semiconductor device according to the first embodiment. The thickness of the substrate 10 was 150 μm, the Si concentration of the first semiconductor layer 11 was 8×10¹⁵/cm³, the Mg concentration of the third semiconductor layer 13 was 6×10¹⁸/cm³, the C concentration of the third semiconductor layer 13 was 1×10¹⁶/cm³, and the thickness of the drain electrode 19 was 2000 nm. Hereafter, this vertical MOSFET is referred to as the vertical MOSFET of Experimental Example 4-1.

Furthermore, a vertical MOSFET having the same structure as that of Experimental Example 4-1 was manufactured, except that the thickness of the substrate 10 was changed to 350 μm. Hereinafter, this vertical MOSFET is referred to as the vertical MOSFET of Experimental Example 4-2. Switching tests were then performed on the vertical MOSFETs of Experimental Examples 4-1 and 4-2 in the same manner as in Experiment 2.

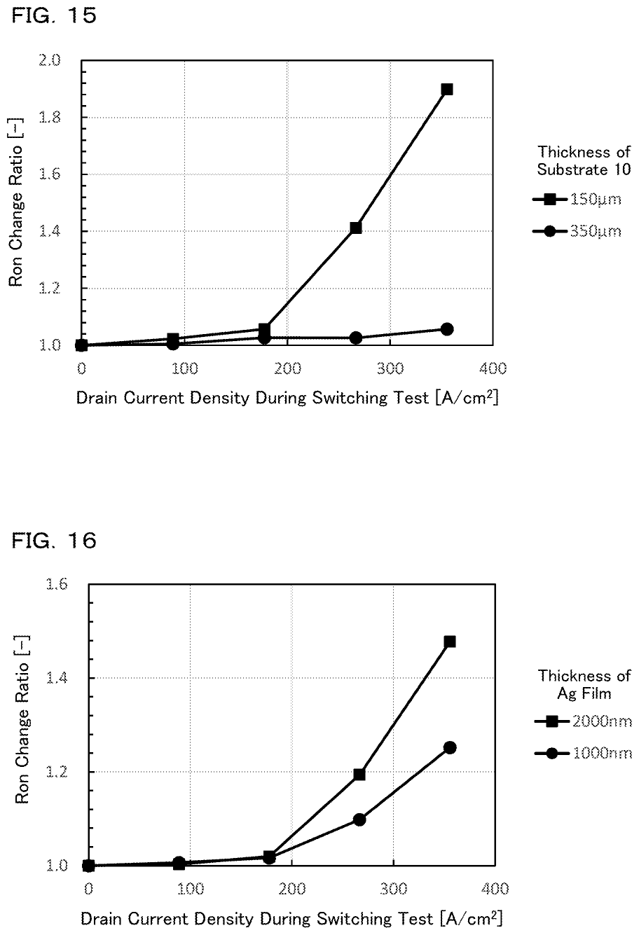

FIG. 15 is a graph showing the relationship between the drain current density during the switching test and the change ratio of on-resistance after the switching test. As shown in FIG. 15, it was found that increasing the thickness of the substrate 10 from 150 μm to 350 μm can reduce the change ratio of on-resistance after the switching test. In particular, for the vertical MOSFET of Experimental Example 4-2 in which the thickness of the substrate 10 was 350 μm, the change ratio of on-resistance was 1.06, which was able to be controlled at 1.1 or less.

### Experiment 5

A vertical MOSFET was manufactured in which the second semiconductor layer 12 was omitted from the semiconductor device according to the first embodiment. The thickness of the substrate 10 was 350 μm, the Si concentration of the first semiconductor layer 11 was 1×10¹⁶/cm³, the Mg concentration of the third semiconductor layer 13 was 6×10¹⁸/cm³, the C concentration of the third semiconductor layer 13 was 1×10¹⁶/cm³, and the thickness of the drain electrode 19 was 2000 nm. Hereafter, this vertical MOSFET is referred to as the vertical MOSFET of Experimental Example 5-1.

Furthermore, a vertical MOSFET having the same structure as that of Experimental Example 5-1 was manufactured, except that the thickness of drain electrode 19 was changed to 1000 nm. Hereinafter, this vertical MOSFET is referred to as the vertical MOSFET of Experimental Example 5-2. Switching tests were then performed on the vertical MOSFETs of Experimental Examples 5-1 and 5-2, in the same manner as in Experiment 2.

FIG. 16 is a graph showing the relationship between drain current density during the switching test and the change ratio of on-resistance after the switching test. As shown in FIG. 16, it was found that reducing the thickness of the drain electrode 19 from 2000 nm to 1000 nm can reduce the change ratio of on-resistance after the switching test.

From Experiments 1 to 5, it was found that the change ratio of on-resistance depends on the presence or absence of the second semiconductor layer 12, the Mg concentration and C concentration of the third semiconductor layer, the thickness of the substrate 10, and the thickness of the drain electrode 19. Therefore, the change ratio of on-resistance can be reduced by providing the second semiconductor layer 12, reducing the C concentration of the third semiconductor layer 13, increasing the thickness of the substrate 10, and reducing the thickness of the drain electrode 19. Specifically, by setting the Mg concentration of the third semiconductor layer 13 to 1×10¹⁹/cm³ or less and the C concentration to 3×10¹⁶/cm³ or less, and by controlling the presence or absence of the second semiconductor layer 12, the thickness of the substrate 10, and the thickness of the drain electrode 19, the change ratio of on-resistance can be controlled at 1.1 or less.

### Second Embodiment

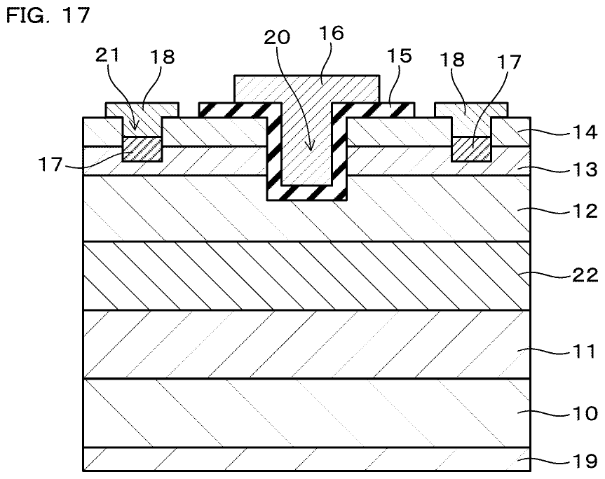

FIG. 17 is a cross-sectional view showing a structure of the semiconductor device according to a second embodiment, taken perpendicular to a main surface of the substrate. As shown in FIG. 17, the semiconductor device according to the second embodiment is manufactured in which a fifth semiconductor layer 22 (fourth n-type layer) is formed between the first semiconductor layer 11 and the second semiconductor layer 12 in the semiconductor device according to the first embodiment. The other structures are the same as those of the first embodiment.

The fifth semiconductor layer 22 is a semiconductor layer made of Si-doped n-GaN. The Si concentration of the fifth semiconductor layer 22 is higher than that of the first semiconductor layer 11 but lower than that of the fourth semiconductor layer 14. By providing the fifth semiconductor layer 22, when current flows perpendicular to the main surface of the substrate 10, the current can be more easily spread in a direction parallel to the main surface of the substrate 10. This allows for a wider current path, thereby reducing the on-resistance. The Si concentration of the fifth semiconductor layer 22 is, for example, 1×10¹⁶ to 1×10¹⁸/cm³. Within this range, sufficient current spreading can be achieved while ensuring breakdown voltage.

The thickness of the fifth semiconductor layer 22 is preferably 10 nm or more. This allows sufficient current spreading. Furthermore, the thickness of the fifth semiconductor layer 22 is preferably 1 μm or less. This ensures breakdown voltage. The thickness of the fifth semiconductor layer 22 is more preferably 0.1 to 1 μm, and even more preferably 0.3 to 0.7 μm.

### Modified Embodiments

In the first and second embodiments, the n-type second semiconductor layer 12 with a Si concentration lower than that of the first semiconductor layer 11 is provided between the first semiconductor layer 11 and the third semiconductor layer 13. However, even if the second semiconductor layer 12 is omitted, by setting the Mg concentration of the third semiconductor layer 13 to 1×10¹⁹/cm³ or less, and the C concentration of the third semiconductor layer 13 to 3×10¹⁶/cm³ or less, and by controlling the thickness of the substrate 10 and the thickness of the drain electrode 19, the change ratio of on-resistance can be controlled at 1.1 or less. However, when the Si concentration of the first semiconductor layer 11 is 5×10¹⁵/cm³ or more, it is preferable to provide the second semiconductor layer 12. The change ratio of on-resistance can be more easily controlled at 1.1 or less compared to when the second semiconductor layer 12 is not provided.

What is claimed is

1. A vertical transistor having a trench insulated gate structure and using a group III nitride semiconductor, the vertical transistor comprising:
a conductive substrate;
a first n-type layer formed on or above the substrate and made of an n-type group III nitride semiconductor;
a p-type layer formed on or above the first n-type layer and made of a p-type group III nitride semiconductor;
a second n-type layer formed on or above the p-type layer and made of an n-type group III nitride semiconductor having an n-type impurity concentration higher than that of the first n-type layer;
a trench formed in a portion of a surface of the second n-type layer and having a depth reaching the first n-type layer;
a gate insulating film formed on a bottom surface and side surfaces of the trench;
a gate electrode formed on the bottom surface and side surfaces of the trench via the gate insulating film;
a source electrode formed on the second n-type layer; and
a drain electrode formed on a back surface of the substrate, wherein
the p-type layer has a p-type impurity concentration of 1×10¹⁹/cm³ or less and a C concentration of 3×10¹⁶/cm³ or less, and
when a switching test is performed by switching the vertical transistor on and off for 2 minutes at a drain current of 350 A/cm², a frequency of 100 kHz, and a duty ratio of 50%, a ratio of the on-resistance after the switching test to the on-resistance before the switching test is 1.1 or less.

2. The vertical transistor according to claim 1, further comprising a third n-type layer having an n-type impurity concentration lower than that of the first n-type layer between the first n-type layer and the p-type layer, wherein
the trench has a depth reaching the third n-type layer, and
the n-type impurity concentration of the first n-type layer is 5×10¹⁵/cm³ or more.

3. A vertical transistor having a trench insulated gate structure and using a group III nitride semiconductor, the vertical transistor comprising:
a conductive substrate;
a first n-type layer formed on or above the substrate and made of an n-type group III nitride semiconductor;
a p-type layer formed on or above the first n-type layer and made of a p-type group III nitride semiconductor;
a second n-type layer formed on or above the p-type layer and made of an n-type group III nitride semiconductor having an n-type impurity concentration higher than that of the first n-type layer;
a trench formed in a portion of a surface of the second n-type layer and having a depth reaching the first n-type layer;
a gate insulating film formed on a bottom surface and side surfaces of the trench;
a gate electrode formed on the bottom surface and side surfaces of the trench via the gate insulating film;
a source electrode formed on the second n-type layer; and
a drain electrode formed on a back surface of the substrate, wherein
a p-type impurity concentration and a C concentration of the p-type layer, a thickness of the substrate, and a thickness of the drain electrode are set so that a ratio of the on-resistance after the switching test to the on-resistance before the switching test is 1.1 or less when a switching test is performed by switching the vertical transistor on and off for 2 minutes at a drain current of 350 A/cm², a frequency of 100 kHz, and a duty ratio of 50%.

4. A vertical transistor comprising:
a conductive substrate;
a first n-type layer formed on or above the substrate and made of an n-type group III nitride semiconductor;
a p-type layer formed on or above the first n-type layer and made of a p-type group III nitride semiconductor;
a second n-type layer formed on or above the p-type layer and made of an n-type group III nitride semiconductor having an n-type impurity concentration higher than that of the first n-type layer;
a third n-type layer formed between the first n-type layer and the p-type layer and made of an n-type group III nitride semiconductor having an n-type impurity concentration lower than that of the first n-type layer;
a trench formed in a portion of a surface of the second n-type layer and having a depth reaching the third n-type layer;
a gate insulating film formed on a bottom surface and side surfaces of the trench;
a gate electrode formed on the bottom surface and side surfaces of the trench via the gate insulating film;
a source electrode formed on the second n-type layer; and
a drain electrode formed on a back surface of the substrate.

5. The vertical transistor according to claim 1, wherein the substrate has a thickness of 300 μm or more.

6. The vertical transistor according to claim 1, wherein the p-type layer has a C concentration of 3×10¹⁵/cm³ or less.

7. The vertical transistor according to claim 1, wherein the drain electrode has a thickness of 1000 nm or less.

8. The vertical transistor according to claim 2, wherein the third n-type layer has an n-type impurity concentration less than or equal to ¾ of the n-type impurity concentration of the first n-type layer.

9. The vertical transistor according to claim 2, further comprising a fourth n-type layer made of an n-type group III nitride semiconductor between the first n-type layer and the third n-type layer,
wherein the fourth n-type layer has an n-type impurity concentration higher than that of the first n-type layer and lower than that of the second n-type layer.

10. The vertical transistor according to claim 2, wherein the distance from a lower surface of the third n-type layer to the bottom surface of the trench is 0.1 to 2.0 μm.

11. The vertical transistor according to claim 2, wherein the distance from the lower surface of the third n-type layer to the bottom surface of the trench is 0.1 to 0.9 times the thickness of the third n-type layer.

12. The vertical transistor according to claim 4, wherein when a switching test is performed by switching the vertical transistor on and off for 2 minutes at a drain current of 350 A/cm², a frequency of 100 kHz, and a duty ratio of 50%, a ratio of the on-resistance after the switching test to the on-resistance before the switching test is 1.1 or less.
